(19) United States
(12) Patent Application Publication
(10) Pub. No.: US 2009/0072328 A1
(43) Pub. Date: Mar. 19, 2009

(54) SEMICONDUCTOR DEVICE AND METHOD OF FABRICATING THE SAME

(75) Inventor: Yun Ik Son, Icheon-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/966,582

(22) Filed: Dec. 28, 2007

(30) Foreign Application Priority Data
Sep. 18, 2007 (KR) 10-2007-0094841

(51) Int. Cl. H01L 29/78; H01L 21/28

(52) U.S. Cl. 257/411; 438/591; 257/E29.255; 257/E21.18

(57) ABSTRACT

A method of fabricating a semiconductor device includes forming a first gate insulating film over a cell region of a semiconductor substrate. A conductive layer is formed over the semiconductor substrate including the cell region and a peripheral region. An oxidizing process is performed on the conductive layer to form a second gate insulating film in the cell region and a third gate insulating film in the peripheral region.

### CROSS-REFERENCES TO RELATED APPLICATIONS

The priority of Korean patent application number 10-2007-0094841, filed on Sep. 18, 2007, which is incorporated by reference in its entirety, is claimed.

### BACKGROUND OF THE INVENTION

The present invention relates to a semiconductor device and more particularly to a semiconductor device including a gate insulating film and a method of fabricating the same.

Due to high integration in semiconductor devices, a size of a semiconductor device such as a Metal Oxide Silicon Field Effect Transistor (MOSFET) has become smaller. As a result, both a line width and a channel length of the gate have also been reduced. In the reduced semiconductor device, it is required to form a thin gate insulating film in order to improve an operating characteristic of the device.

A gate insulating film reaches a physical limit in electric characteristics as the thickness of the gate insulating film is reduced. As a result, it is difficult to secure the reliability of the gate insulating film. That is, if a thickness of a silicon oxide film is reduced, a direct tunneling current is increased. The increased leakage current between the gate and the channel thereby increases power consumption. Thus, it is difficult to secure the reliability of the gate insulating film.

In order to overcome the thickness limit of the gate insulating film, the gate insulating film can be replaced with a material having a dielectric constant higher than that of the silicon oxide film (e.g., a high dielectric material, which is referred to as a “high-k material”). This high-k material may reduce the tunneling current because a physical thickness of the gate insulating film is thicker while an equivalent oxide thickness (EOT) of the high-k material is maintained as that of the silicon oxide film.

However, in the high-k material, the electron mobility is reduced because there are a lot of interface-trapped charges and fixed charges between a semiconductor substrate and the gate insulating film. In addition, the high-k is crystallized in a high thermal treatment during the manufacturing process for a semiconductor device, thereby increasing leakage current due to electrical conduction through a crystal grain boundary and defect level of the high-k material. In other words, the thermal stability for the high-k material is low to degrade the reliability of the gate insulating film.

### BRIEF SUMMARY OF THE INVENTION

Embodiments of the present invention are directed to as semiconductor device. According to an embodiment of the invention, the semiconductor device includes a gate insulating film formed with a high-k material in a cell region and a peripheral region. The gate insulating film of the cell region is formed of a metal silicate dielectric film, and the gate insulating film of the peripheral region is formed of a metal dielectric film having a larger dielectric constant than that of the gate insulating film of the cell region. As a result, in the cell region, the reliability of the gate insulating film is improved, and in the peripheral region capacitance of the gate insulating film is increased as well as the operation speed.

According to an embodiment of the present invention, a method of fabricating a semiconductor device includes: forming a first gate insulating film over a cell region of a semiconductor substrate. A conductive layer is formed over the semiconductor substrate including the cell region and a peripheral region. An oxidizing process is performed on the conductive layer to form a second gate insulating film in the cell region and a third gate insulating film in the peripheral region.

According to an embodiment of the present invention, a semiconductor device includes: the different gate insulating films in the cell region and the peripheral region formed according to the above described method.

### BRIEF DESCRIPTION OF THE DRAWINGS

FIGS. 1a to 1g are cross-sectional views illustrating a method of fabricating a semiconductor device according to an embodiment of the present invention.

### DESCRIPTION OF EMBODIMENTS

The present invention relates to a semiconductor device. According to an embodiment of the present invention, the semiconductor device includes different gate insulating films in a cell region and a peripheral region.

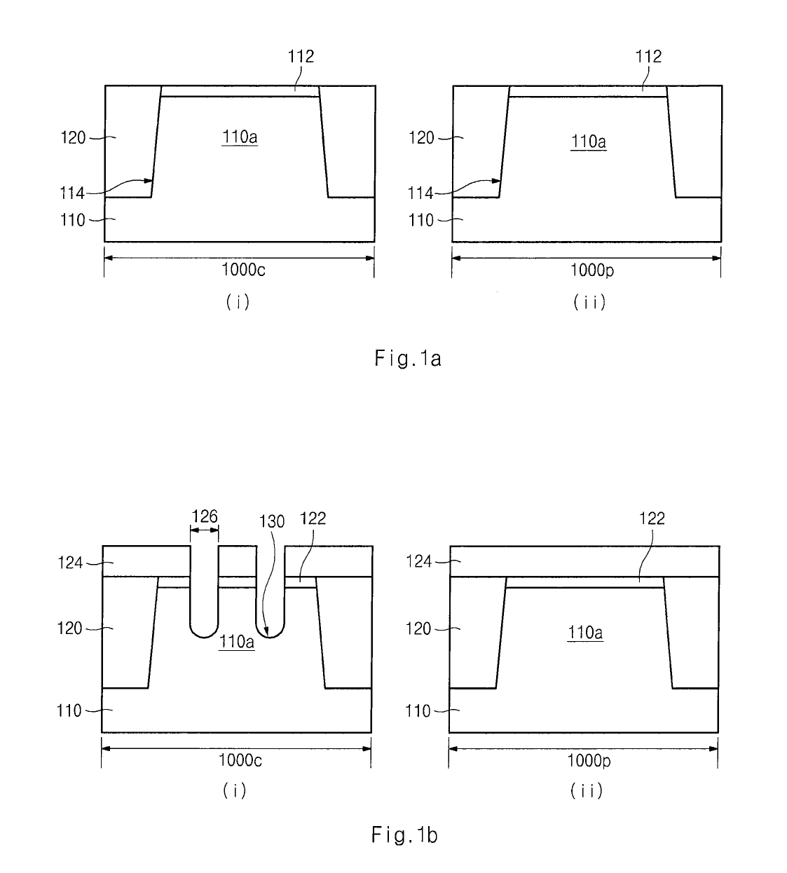

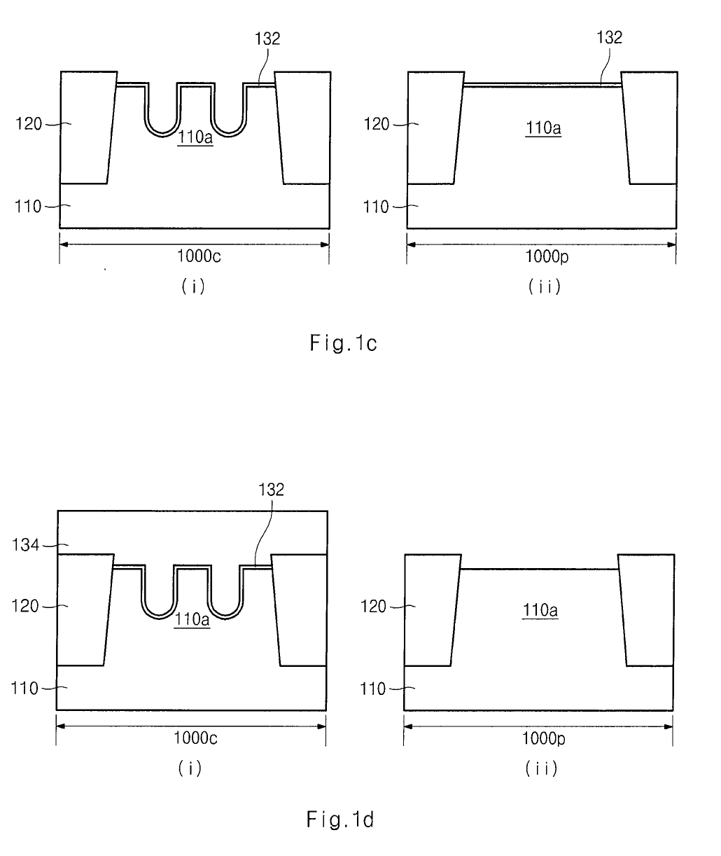

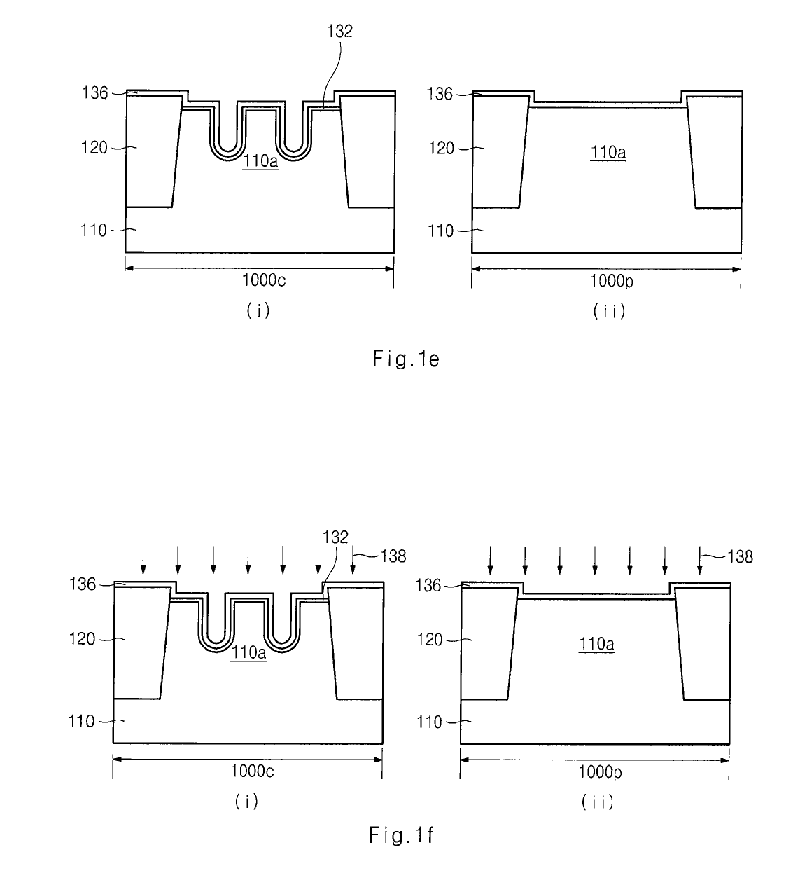

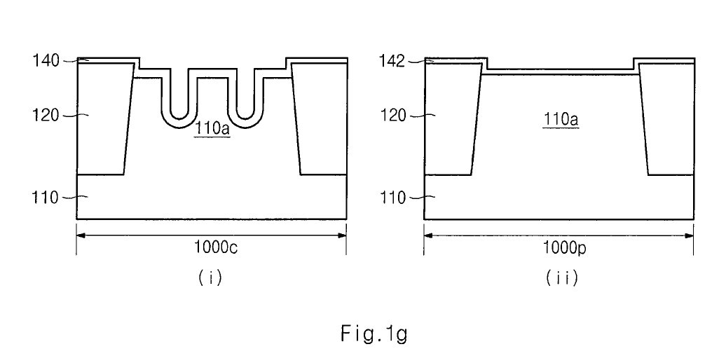

FIGS. 1a to 1g are cross-sectional views illustrating a method of fabricating a semiconductor device according to an embodiment of the present invention. A pad insulating film 112 is formed over a semiconductor substrate 110 including a cell region 1000c and a peripheral region 1000p. Pad insulating film 112 includes one film selected from the group consisting of an oxide film, a nitride film and a combination thereof. A portion of pad insulating film 112 and semiconductor substrate 110 is etched using a mask that defines an active region to form a trench 114 that defines a device isolating region.

An insulating film for device isolation (not shown) is formed over a semiconductor substrate 110 to fill trench 114. The insulating film for device isolation includes one film selected from the group consisting of a spin-on-dielectric (SOD) oxide film, a high density plasma (HDP) oxide film and a combination thereof. The insulating film for device isolation is planarized until pad insulating film 112 is exposed to form a device isolation structure 120 that defines an active region 110a. The device film for isolating insulation is planarized by a chemical mechanical polishing (CMP) method or an etch-back method.

Referring to FIG. 1b, pad insulating film 112 is removed to expose active region 110a. A buffer oxide film 122 is formed over exposed active region 110a. A hard mask layer 124 is formed over semiconductor substrate 110. Hard mask layer 124 and buffer oxide film 122 are selectively etched using a mask that defines a recess gate region (not shown) in a cell region 1000c to form a recess region 126. A portion of active region 110a at the bottom of the recess region 126 is etched to form a recess 130.

Referring to FIG. 1c, hard mask layer 124 and buffer oxide film 122 are removed to expose active region 110a of cell region 1000c and peripheral region 1000p. A first gate insulating film 132 is formed over exposed active region 110a. First gate insulating film 132 includes an oxide film formed by one selected from the group consisting of a dry oxidation method, a wet oxidation method, a radical oxidation method and combinations thereof.

Referring to FIG. 1d, a photoresist film (not shown) is formed over first gate insulating film 132 and semiconductor substrate 110. The photoresist film is exposed and developed using a mask (not shown) that opens peripheral region 1000p to form a photoresist pattern 134 that exposes first gate insulating film 132 in peripheral region 1000p. First gate insulating film 132 in peripheral region 1000p is removed to expose active region 110a in peripheral region 1000p. First gate insulating film 132 is removed by a wet-cleaning process using HF or a buffer oxide etchant (BOE).

Referring to FIG. 1e, photoresist pattern 134 of FIG. 1d is then removed. A metal layer 136 is formed over semiconductor substrate 110. Metal layer 136 includes one layer selected from the group consisting of a hafnium (Hf) layer, a lanthanum (La) layer, a zirconium (Zr) layer, an aluminum (Al) layer and combinations thereof. Metal layer 136 is formed by a physical vapor deposition (PVD) method and an atomic layer deposition (ALD) method.

Referring to FIGS. 1f and 1g, an oxidation process 138 is performed on metal layer 136 to form a second gate insulating film to 140 in cell region 1000c and a third gate insulating film 142 in peripheral region 1000p. An oxidation process 138 is performed under an atmosphere containing oxygen (O₂) by a rapid thermal annealing (RTA) method. The RTA method is performed at a temperature in the range of about 600° C. to 1100° C. Second gate insulating film 140 includes a metal silicate dielectric film formed using first gate insulating film 132 and metal layer 136. Third gate insulating film 142 includes a metal dielectric film. Third gate insulating film 142 has a larger dielectric constant than that of the second gate insulating film 140.

The gate insulating film in cell region 1000c includes a metal silicate insulating film to improve an interface characteristic and have thermal stability. The gate insulating film in peripheral region 1000p includes a metal insulating film to increase the capacitance of the gate insulating film, thereby improving an operation speed of the device. Subsequent processes are performed using well known processes including a process of forming a gate, a process of forming a bit line, and so on, to obtain a transistor.

As described above, according to an embodiment of the present invention, a gate insulating film is formed of a high-k material to secure reliability of the gate insulating film. Also, it is possible to form two different gate insulating films that have a different dielectric constant in a cell region and peripheral region of a memory device.

The gate insulating film in the cell region includes a metal silicate dielectric film to improve an interface characteristic and secure thermal stability. The gate insulating film in the peripheral region includes a metal dielectric film to have a larger dielectric constant than that of the gate insulating film in the cell region, thereby increasing capacitance. As a result, a leakage current of the device can be reduced, and a short channel margin can be secured.

The above embodiments of the present invention are illustrative and not limitative. Various alternatives and equivalents are possible. The invention is not limited by the type of deposition, etching polishing, and patterning steps described herein. Nor is the invention limited to any specific type of semiconductor device. For example, the present invention may be implemented in a dynamic random access memory (DRAM) device or non-volatile memory device. Other additions, subtractions, or modifications are obvious in view of the present disclosure and are intended to fall within the scope of the appended claims.

What is claimed is:

1. A method of fabricating a semiconductor device, the method comprising:
forming a first gate insulating film over a cell region of a semiconductor substrate;
forming a conductive layer over the semiconductor substrate including the cell region and a peripheral region; and
performing an oxidizing process on the conductive layer to form a second gate insulating film in the cell region and a third gate insulating film in the peripheral region.

2. The method of claim 1, wherein the first gate insulating film includes an oxide film formed by a method selected from the group consisting of a dry oxidizing method, a wet oxidizing method, a radical oxidizing method and combinations thereof.

3. The method of claim 2, wherein the oxide film includes the first gate insulating film includes silicon oxide (SiO₂).

4. The method of claim 1, wherein the process of forming the first gate insulating film includes:
forming the first gate insulating film over the semiconductor substrate including the cell region and the peripheral region; and
removing the first gate insulating film in the peripheral region.

5. The method of claim 4, wherein the process of removing the first gate insulating film is performed by a cleaning process including HF or buffer oxide etchant (BOE).

6. The method of claim 1, wherein the conductive layer includes a layer selected from the group consisting of a hafnium (Hf) layer, a lanthanum (La) layer, a zirconium (Zr) layer, an aluminum (Al) layer, and combinations thereof.

7. The method of claim 1, wherein the process of forming the conductive layer is performed by a physical vapor deposition (PVD) method or an atomic layer deposition (ALD) method.

8. The method of claim 1, wherein the oxidizing process is performed by a thermal treatment under an oxygen atmosphere.

9. The method of claim 8, wherein the thermal treatment is performed by a rapid thermal annealing (RTA) method.

10. The method of claim 8, wherein the thermal treatment is performed under a temperature in the range of about 600° C. to 1,100° C.

11. The method of claim 1, wherein a dielectric constant of the third gate insulating film is greater than that of the second gate insulating film.

12. A semiconductor device comprising the different gate insulating films in the cell region and the peripheral region formed according to the method of claim 1.
